(19) United States
(12) Patent Application Publication
(10) Pub. No.: US 2004/0257848 A1
(43) Pub. Date: Dec. 23, 2004

(54) Method for adjusting the threshold voltage of a memory cell

(75) Inventors: Yi Chou Chen, Hsinchu (TW); Chih-Yuan Lu, Hsinchu (TW)

Correspondence Address: MARTINE & PENILLA, LLP, 710 LAKEWAY DRIVE, SUITE 170, SUNNYVALE, CA, 94085, US

(73) Assignee: MACRONIX INTERNATIONAL CO., LTD.

(21) Appl. No.: 10/465,120

(22) Filed: Jun. 18, 2003

(51) Int. Cl. G11C 13/00

(52) U.S. Cl. 365/113

(57) ABSTRACT

In a method for adjusting a threshold voltage of a memory cell, energy is applied into a film comprised of a material capable of changing threshold voltage. By way of example, the film may be comprised of a chalcogenide material. The energy may be applied in the form of an electrical pulse (voltage pulse or current pulse), a pulse of light (a laser pulse), a pulse of heat, or microwave energy. The energy pulses may have a predetermined magnitude, may have a predetermined profile, and may be applied for a predetermined duration to change the threshold voltage. A method for adjusting a threshold voltage of a chalcogenide material also is described. In this method, energy is applied into a chalcogenide material.

### CROSS-REFERENCE TO RELATED APPLICATIONS

This application is related to the following applications: (1) U.S. patent application Ser. No. ______ (Attorney Docket No. MXICP021), filed on the same day as the instant application, and entitled “Transistor-Free Random Access Memory”; and (2) U.S. patent application Ser. No. ______ (Attorney Docket No. MXICP022), filed on the same day as the instant application, and entitled “Multi-Level Memory Device and Methods for Programming and Reading the Same.” The disclosures of these related applications are incorporated herein by reference.

### BACKGROUND OF THE INVENTION

The present invention relates generally to memory devices and, more particularly, to a method for adjusting a threshold voltage of a memory cell.

Chalcogenide memory cells are nonvolatile and can change phases relatively quickly. Therefore, such memory cells have great potential to be the next generation memory. To date, developmental work regarding chalcogenide memory cells has focused on the ability of chalcogenide materials to change between an amorphous phase and a crystalline phase. In particular, developmental work for memory/solid state device applications has focused on the resistance of chalcogenide materials, and developmental work for optical applications has focused on the n and k changes of chalcogenide materials. For example, FIGS. 7 and 8 of U.S. Pat. No. 3,530,441 show that the resistance of a chalcogenide material can be varied by applying energy to the material. At present, those skilled in the art consider the threshold voltage, Vₜₕ, of chalcogenide materials to be a “messy” property and, consequently, they have not focused on this property in developmental work for memory/solid state device applications or optical applications.

### SUMMARY OF THE INVENTION

Broadly speaking, the present invention enables the threshold voltage, Vₜₕ, of a memory cell as well as the Vₜₕ of a chalcogenide material to be tuned or adjusted.

In accordance with one aspect of the present invention, a method for adjusting a threshold voltage of a memory cell is provided. In this method, energy is applied into a film comprised of a material capable of changing threshold voltage. In one embodiment, the film is comprised of a chalcogenide material.

In one embodiment, the applying of energy includes applying an electrical pulse into the film. In one embodiment, the electrical pulse is a voltage pulse, and the voltage pulse has a predetermined magnitude, has a predetermined profile, and is applied for a predetermined duration. In one embodiment, the electrical pulse is a current pulse, and the current pulse has a predetermined magnitude, has a predetermined profile, and is applied for a predetermined duration.

In one embodiment, the applying of energy includes applying a pulse of light into the film. In one embodiment, the pulse of light is a laser pulse, and the laser pulse has a predetermined magnitude, has a predetermined profile, and is applied for a predetermined duration.

In one embodiment, the applying of energy includes applying a pulse of heat into the film. In one embodiment, the pulse of heat has a predetermined magnitude, has a predetermined profile, and is applied for a predetermined duration. In one embodiment, the applying of energy includes applying a pulse of microwave energy into the film. In one embodiment, the pulse of microwave energy has a predetermined magnitude, has a predetermined profile, and is applied for a predetermined duration.

In accordance with another aspect of the present invention, a method for adjusting a threshold voltage of a chalcogenide material is provided. In this method, energy is applied into a chalcogenide material.

It will be apparent to those skilled in the art that the method of adjusting the Vₜₕ of the present invention can be applied in numerous memory/solid state device applications. One of the significant advantages of the method of the present invention is the speed with which the Vₜₕ can be adjusted. After the application of the energy pulses, the quenching time is usually shorter than about 50 nanoseconds (ns). In contrast, it usually takes at least 100 ns to change the phase of a chalcogenide material.

It is to be understood that the foregoing general description and the following detailed description are exemplary and explanatory only and are not restrictive of the invention, as claimed.

### BRIEF DESCRIPTION OF THE DRAWINGS

The accompanying drawings, which are incorporated in and constitute part of this specification, illustrate exemplary embodiments of the invention and together with the description serve to explain the principles of the invention.

FIG. 1 is an I-V curve of a chalcogenide memory cell.

FIG. 2 is a graph of Vₜₕ versus pulse voltage at different pulse widths.

FIG. 3 is a schematic diagram that illustrates the application of electrical pulses into a chalcogenide memory cell.

FIG. 4 illustrates an exemplary duration (or profile) for a pulse of energy.

FIG. 5 is a schematic diagram that illustrates the application of light pulses into a chalcogenide memory cell.

FIG. 6 is a schematic diagram that illustrates the application of heat pulses into a chalcogenide memory cell.

FIG. 7 is a cross-sectional view of a memory cell structure in which the method of adjusting the Vₜₕ of a material capable of changing Vₜₕ may be implemented.

### DETAILED DESCRIPTION OF EXEMPLARY EMBODIMENTS

Several exemplary embodiments of the invention will now be described in detail with reference to the accompanying drawings.

In accordance with the present invention, the threshold voltage, Vₜₕ, of a material capable of changing Vₜₕ is adjusted by applying energy into the material. By way of example, materials capable of changing Vₜₕ include chalcogenide materials, particularly amorphous chalcogenide materials, and other semiconductor materials, e.g., amorphous silicon. As used herein, the term “chalcogenide material” refers to an alloy containing at least one element from the Group 16 (old-style: Group VI) elements of the periodic table, i.e., O, S, Se, Te, and Po. Exemplary chalcogenide materials are disclosed in U.S. Pat. No. 5,177,567 and the list of patents incorporated by reference in the '567 patent. This list includes U.S. Pat. Nos. 3,271,591, 3,343,034, 3,571,669, 3,571,670, 3,571,671, 3,571,672, 3,588,638, 3,611,063, 3,619,732, 3,656,032, 3,846,767, 3,875,566, 3,886,577, and 3,980,505. The disclosure of the '567 patent and the disclosures of the listed patents incorporated by reference in the '567 patent are incorporated by reference herein.

FIG. 1 is an I-V curve of a chalcogenide memory cell. As shown in FIG. 1, Vₜₕ occurs at a value of 1 volt (V) (normalized). Thus, when a voltage below Vₜₕ is applied to the cell, the current is very low. On the other hand, when a voltage above Vₜₕ is applied to the cell, the current jumps to a significantly higher level. As shown in FIG. 1, the difference in the current for voltages above and below Vₜₕ is readily discernable. As will be explained in more detail below, the Vₜₕ of the cell may be adjusted either higher or lower (as indicated by the double-ended arrow in FIG. 1) by applying energy into the chalcogenide film.

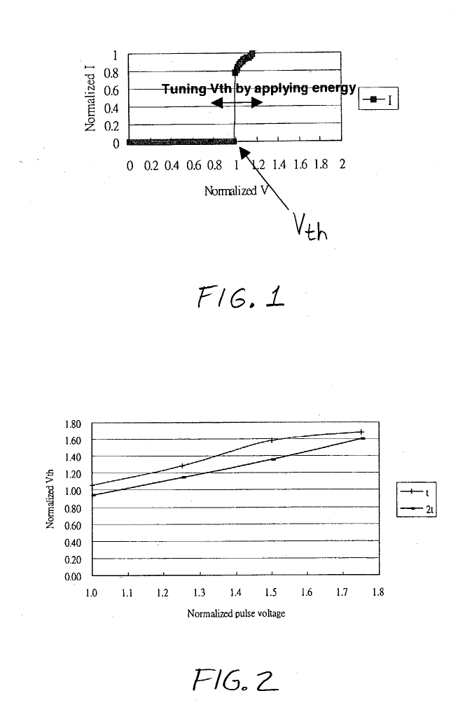

FIG. 2 is a graph of Vₜₕ versus pulse voltage at different pulse widths. The pulse width for curve 100 (the top curve) was t, whereas the pulse width for curve 102 (the bottom curve) was 2t. Curves 100 and 102 demonstrate that the Vₜₕ of a chalcogenide memory cell can be adjusted by applying a certain voltage (or current) pulse with a certain pulse width (or profile) into the cell.

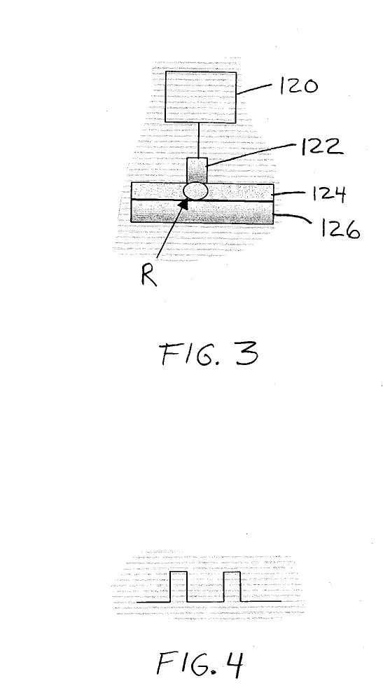

The energy may be applied into the material capable of changing Vₜₕ, e.g., a chalcogenide film in a memory cell, in any suitable form. By way of example, the energy may be applied in the form of electrical pulses, light pulses, microwave energy, or heat pulses. FIG. 3 is a schematic diagram that illustrates the application of electrical pulses into a chalcogenide memory cell. As shown in FIG. 3, a voltage/current source 120 is coupled to top electrode 122 of the chalcogenide memory cell, which also includes chalcogenide film 124 and bottom electrode 126. When a voltage pulse (or current pulse) is applied into the cell, the portion of chalcogenide film 124 indicated by the arrow labeled R undergoes a change in Vₜₕ. An exemplary duration (or profile) for the voltage pulse (or current pulse) is shown in FIG. 4.

FIG. 5 is a schematic diagram that illustrates the application of light pulses into a chalcogenide memory cell. As shown in FIG. 5, light source 130 directs pulses of light into the cell. In one embodiment, the light pulses are laser pulses. When a light pulse, e.g., a laser pulse, is applied into the cell, the portion of chalcogenide film 124 indicated by the arrow labeled R undergoes a change in Vₜₕ. By way of example, the light pulses may have the duration (or profile) shown in FIG. 4. Those skilled in the art will appreciate that the top electrode has been omitted from FIG. 5, and that the top electrode may be provided above film 124 at a location that is offset from the region in which the light pulse is applied.

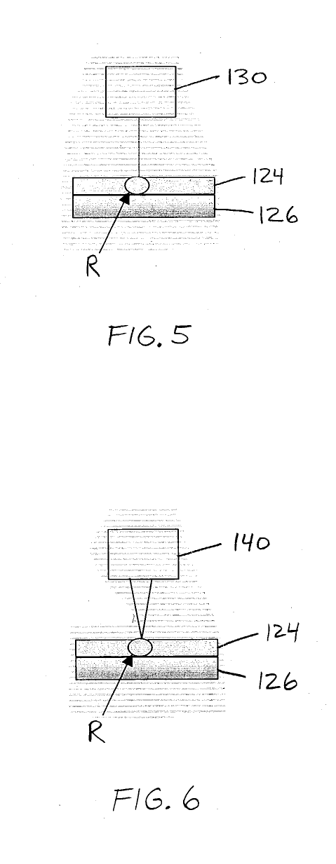

FIG. 6 is a schematic diagram that illustrates the application of heat pulses into a chalcogenide memory cell. As shown in FIG. 6, heat source 140 emits pulses of heat into the cell. In one embodiment, heat source 140 is a heated object. In another embodiment, heat source 140 is a microwave generator. When a pulse of heat, e.g., a pulse of heat from a heated object or a pulse of microwave energy, is applied into the cell, the portion of the chalcogenide film 124 indicated by the arrow labeled R undergoes a change in Vₜₕ. By way of example, the pulses of heat may have the duration (or profile) shown in FIG. 4. Those skilled in the art will appreciate that the top electrode has been omitted from FIG. 6, and that the top electrode may be provided above film 124 at a location that is offset from the region in which the pulse of heat is applied.

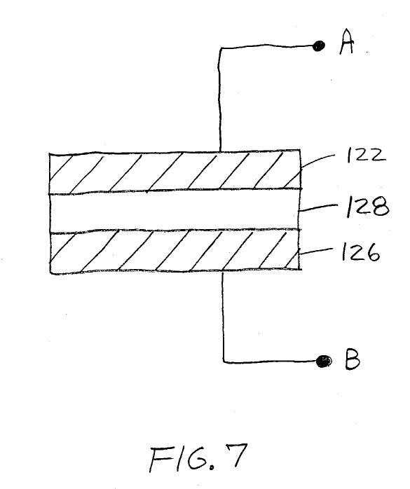

FIG. 7 is a cross-sectional view of a memory cell structure in which the method of adjusting the Vₜₕ of a material capable of changing Vₜₕ may be implemented. As shown in FIG. 7, the memory cell structure includes top electrode 122, a film 128 of a material capable of changing Vₜₕ, and bottom electrode 126. Top electrode 126 and bottom electrode 128 may be formed of any suitable conductive material, e.g., a metal, a metalloid, a semiconductor, e.g., silicon, an element, a compound, an alloy, or a composite. By way of example, film 128 may be formed of a chalcogenide material or amorphous silicon. It should be noted that these materials are exemplary only and that other materials capable of changing Vₜₕ also may be used to form film 128. In a memory cell array, electrical connections A and B to top electrode 122 and bottom electrode 126, respectively, are provided. By way of example, connection A may be to a bit line and connection B may be to a word line. Once the Vₜₕ of film 128 has been adjusted by applying energy in accordance with the method described herein, the state of the memory cell structure can be determined by checking the current flowing through the cell.

It will be apparent to those skilled in the art that the method of adjusting the Vₜₕ of the present invention can be applied in numerous memory/solid state device applications. One of the significant advantages of the method of the present invention is the speed with which the Vₜₕ can be adjusted. After the application of the energy pulses, the quenching time is usually shorter than about 50 nanoseconds (ns). In contrast, it usually takes at least 100 ns to change the phase of a chalcogenide material.

In summary, the present invention provides a method for adjusting the Vₜₕ of a memory cell, and a method for adjusting the Vₜₕ of a chalcogenide material. The invention has been described herein in terms of several exemplary embodiments. Other embodiments of the invention will be apparent to those skilled in the art from consideration of the specification and practice of the invention. The embodiments and preferred features described above should be considered exemplary, with the scope of the invention being defined by the appended claims and their equivalents.

What is claimed is:

1-13. (Canceled).

14. A method for adjusting a threshold voltage of an electrical memory cell, comprising:
applying energy into a single film comprised of a chalcogenide material to adjust a threshold voltage of the film.

15. The method of claim 14, wherein the applying of energy comprises:
applying an electrical pulse into the film.

16. The method of claim 15, wherein the electrical pulse is a voltage pulse.

17. The method of claim 16, wherein the voltage pulse has a predetermined magnitude, has a predetermined profile, and is applied for a predetermined duration.

18. The method of claim 15, wherein the electrical pulse is a current pulse.

19. The method of claim 18, wherein the current pulse has a predetermined magnitude, has a predetermined profile, and is applied for a predetermined duration.

20. The method of claim 14, wherein the applying of energy comprises:
applying a pulse of light into the film.

21. The method of claim 20, wherein the pulse of light is a laser pulse.

22. The method of claim 21, wherein the laser pulse has a predetermined magnitude, has a predetermined profile, and is applied for a predetermined duration.

23. The method of claim 14, wherein the applying of energy comprises:
applying a pulse of heat into the film.

24. The method of claim 23, wherein the pulse of heat has a predetermined magnitude, has a predetermined profile, and is applied for a predetermined duration.

25. The method of claim 14, wherein the applying of energy comprises:
applying a pulse of microwave energy into the film.

26. The method of claim 25, wherein the pulse of microwave energy has a predetermined magnitude, has a predetermined profile, and is applied for a predetermined duration.

27-39. (Canceled).
